(19) United States
(12) Patent Application Publication
(10) Pub. No.: US 2025/0116692 A1
(43) Pub. Date: Apr. 10, 2025

(54) SENSOR ASSEMBLY

(71) Applicants: FOXCONN (KUNSHAN) COMPUTER CONNECTOR CO., LTD., Kunshan (CN); FOXCONN INTERCONNECT TECHNOLOGY LIMITED, Grand Cayman (KY)

(72) Inventors: TING-TING YIN, Kunshan (CN); JIAN-KUANG ZHU, Kunshan (CN); KUO-CHUN HSU, New Taipei (TW)

(21) Appl. No.: 18/897,856

(22) Filed: Sep. 26, 2024

(30) Foreign Application Priority Data
Oct. 5, 2023 (CN) 202311279055.6

(51) Int. Cl. G01R 29/08

(52) U.S. Cl. CPC G01R 29/0878

(57) ABSTRACT

A sensor assembly includes: an insulating shell having a receiving cavity with an insertion opening; an insulating base; and a sensor fixed in the insulating base for recording electromagnetic waves and for electrically connecting to a cable; wherein the insulating base is inserted into and contained in the receiving cavity of the insulating shell from the insertion opening and a working surface of the sensor is face to face attached to a first inside of the insulating shell.

### BACKGROUND OF THE INVENTION

### Field of the Invention

The present invention relates to a sensor assembly with a sensor electrically connected with a cable.

### Description of Related Arts

China Patent No. 208489412 discloses a sensor including a chip, two terminals, and two cables. The terminals are connected with the chip and an insulating slice is injection-molded around the terminals. A larger insulating housing is injection-molded around the terminals, the chip, and one end of the cables. The chip is covered with the insulating slice and the insulating housing such that a sensing distance of the sensor may not be accurate.

Therefore, it is desired to provide a new sensor assembly.

### SUMMARY OF THE INVENTION

An object of the present invention is to provide a sensor assembly with an accurate sensing distance and an easy operation.

To achieve the above-mentioned object, a sensor assembly comprises: an insulating shell having a receiving cavity with an insertion opening; an insulating base; and a sensor fixed in the insulating base for recording electromagnetic waves and for electrically connecting to a cable; wherein the insulating base is inserted into and contained in the receiving cavity of the insulating shell from the insertion opening and a working surface of the sensor is face to face attached to a first inside of the insulating shell.

Other advantages and novel features of the invention will become more apparent from the following detailed description of the present embodiment when taken in conjunction with the accompanying drawings.

### BRIEF DESCRIPTION OF THE DRAWING

FIG. 1 is a perspective view of a sensor assembly of the present invention;

FIG. 2 is an exploded perspective view of the sensor assembly in FIG. 1;

FIG. 3 is a further exploded view of the sensor assembly in FIG. 2 without the insulating shell;

FIG. 4 is a cross-sectional view of the sensor assembly taken along line A-A in FIG. 2; and

FIG. 5 is a cross-sectional view of the sensor assembly taken along line B-B in FIG. 1.

### DETAILED DESCRIPTION OF THE PREFERRED EMBODIMENT

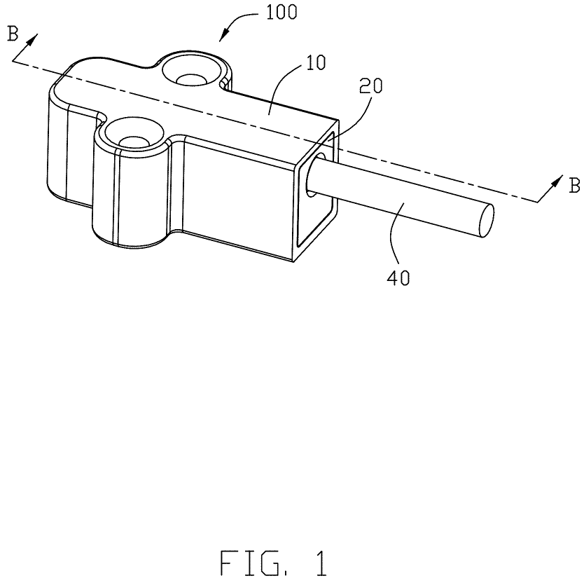

Referring to FIGS. 1-5, a sensor assembly 100 of an embodiment of this present invention includes an insulating shell 10, an insulating base 20, and a sensor 30. The sensor in this embodiment is to record electromagnetic waves. The sensor 30 is contained and fixed in a receiving cavity 101 of the insulating shell 10 and transmits signals through a cable 40. The insulating shell 10 is substantially a sealed structure except for an insertion opening 11 at a rear end thereof. The insulating base 20 with the sensor and the cable is forwards inserted and contained in the insulating shell 10 from the insertion opening 11, and the cable 40 extends rearwards out of the insulating shell 10 so that the manufacture of the assembly 100 is simple, the operation of the assembly is convenient, and the sensor assembly can guarantee good sealing.

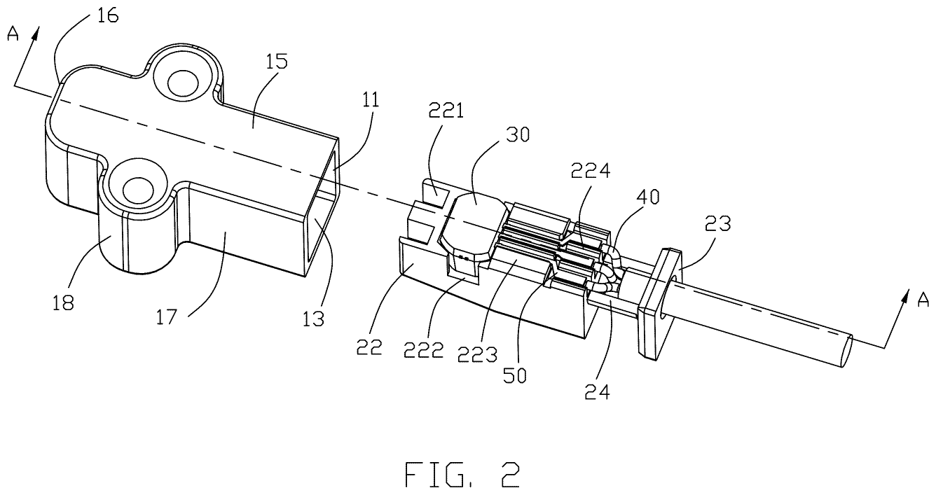

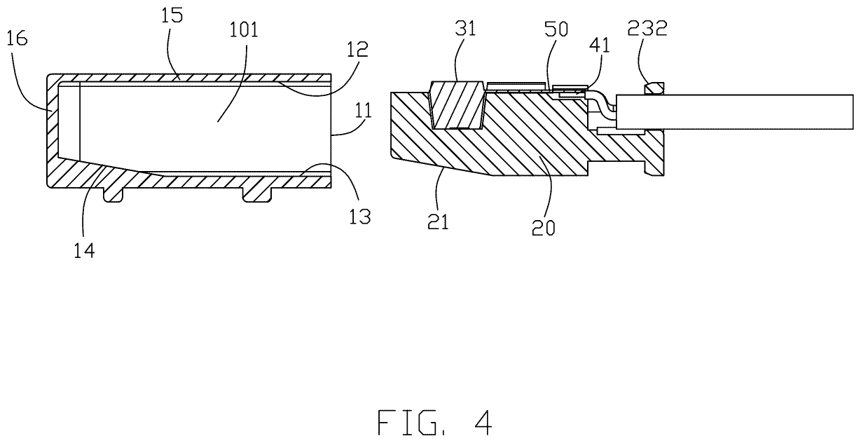

Referring to FIG. 2 and FIG. 4, the insulating shell 10 defines a first inside 12, a first outside 15 opposite to the first inside 12 at an upper side thereof, a second or front outside 16 opposite to the insertion opening 11 and two third outsides 17 connecting the first and second outsides. Two mounting lugs 18 extend from the third outsides 17.

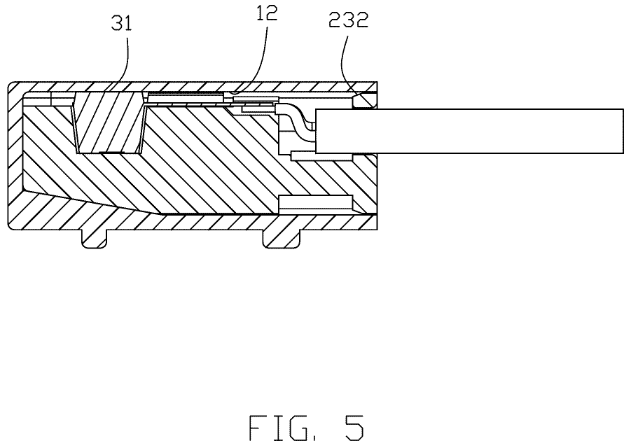

Referring to FIGS. 4-5, the sensor 30 has a working surface 31, the working surface 31 is closely attached to the first inside 12 of the insulating shell 10 to achieve a precise sensing distance, thereby improving the sensing performance of the sensor. The insulating shell 10 defines a second inside 13 facing the first inside 12. The second inside 13 has a first slope 14 facing the first inside 12 and the insertion opening 11. The insulating base 20 includes a second slope 21, and the second slope 21 can slides along the first slope 14. Therefore, the insulating base 20 is pushed towards the first inside 12 guiding by the second slope along the first slop, so as to get the sensor in place and realize good sealing effect.

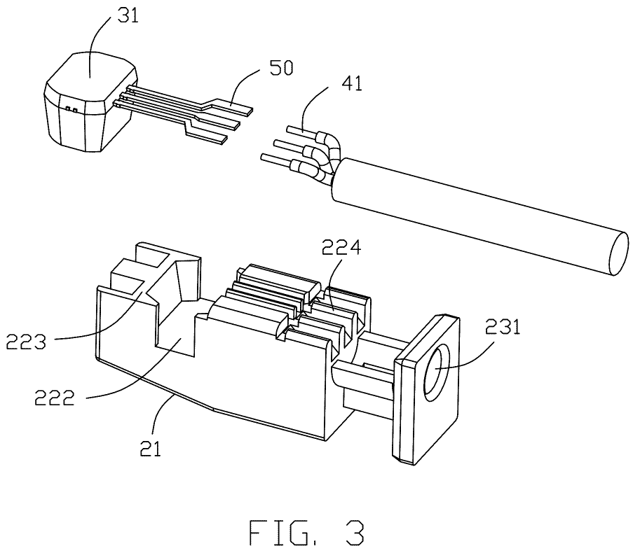

Referring to FIGS. 2-3, the insulating base 20 includes a main portion 22, an upright portion 23 and a transverse portion 24 connecting the main portion 22 and the upright portion 23. The sensor 30 is received in the main portion 22, the upright portion 23 seals the insertion opening 11. The end of the cable 40 passes through a round hole 231 of the upright portion 23, and the upright portion 23 has a guide slope 232 facing forwards, so as to lead the insulating base 20 into a positive position of the insulating shell 10. Therefore, the insulating shell 10 is matched with the upright portion 23 to achieve the fully enclosed sealing effect. In addition, the main portion 22 has two cutting grooves 221 at a front end thereof. The main portion 22 has a first outer face 223 facing the first inside 12 of the insulating shell 10. As shown in FIG. 4, the sensor 30 is received in the insulating base 20 and then is commonly inserted into the insulating shell 10 together. The main portion 22 has a receiving notch 222 recessed from the first outer face 223. The sensor 30 is fixed in the receiving notch 222, and the receiving notch 222 goes through the main portion 22 simultaneously in the direction perpendicular to the cable 40. The working surface 31 of the sensor 30 exposes to the first outer face 223, and the second slope 21 of the insulating base 20 slides along the first slope 14 and guides the insulating base 20 to move towards the first inside 12, and the working surface 31 of the sensor 30 gradually approaches the first inside 12 until the working face 31 is face to face attached to the first inside 12, so as to achieve an accurate sensing distance. As shown in FIGS. 2-4, the sensor 30 is connected with the cable 40 by a plurality of metal terminals 50 and the front end of the cable 40 is supported by the transverse portion 24. The first outer face 223 further has a plurality of ribs 224 and the metal terminals 50 are correspondingly arranged between the ribs 224, so that the interference between adjacent metal terminals can be prevented. Furthermore, the metal terminals 50 are connected with front exposing conductive cores 41 of the cable 40, and the ribs 224 extending between the adjacent cores 41 makes the distance between adjacent cores 41 gradually increase towards the insertion direction, so as to prevent the short circuit caused by the interference between the adjacent cores 41. Accordingly, the distance between the adjacent metal terminals 50 gradually increases towards the cores 41. The front exposing conductive cores 41 are located below corresponding rear ends of the metal terminals.

The above-mentioned embodiments are only preferred embodiments of the present invention, and should not limit the scope of the present invention, any simple equivalent changes and modifications made according to the claims of the present invention and the contents of the description should still belong to the present invention.

1. A sensor assembly comprising:
an insulating shell having a receiving cavity with an insertion opening;
an insulating base; and
a sensor fixed in the insulating base for recording electromagnetic waves and for electrically connecting to a cable;
wherein the insulating base is inserted into and contained in the receiving cavity of the insulating shell from the insertion opening and a working surface of the sensor is face to face attached to a first inside of the insulating shell.

2. The sensor assembly as claimed in claim 1, wherein the insulating shell has a second inside facing the first inside, the second inside has a first slope facing the insertion opening, the insulating base has a second slope, and the second slope slides along the first slope to guide the insulating base to move towards the first inside of the insulating shell.

3. The sensor assembly as claimed in claim 2, wherein the insulating base includes a main portion holding the sensor, an upright portion sealing the insertion opening and a transverse portion connecting with the main portion and the upright portion, and the cable extends through a round hole of the upright portion.

4. The sensor assembly as claimed in claim 3, wherein the main portion has a first outer face facing the first inside of the insulating shell and the working surface of the sensor is exposed to the first outer face of the insulating base.

5. The sensor assembly as claimed in claim 4, wherein the main portion has a receiving notch recessed from the first outer face and penetrating through the main portion, and the sensor is received in the receiving notch.

6. The sensor assembly as claimed in claim 4, further comprising a plurality of metal terminals connected between the sensor and exposed conductive cores of the cable.

7. The sensor assembly as claimed in claim 6, wherein the first outer face defines a plurality of ribs, rear ends of the metal terminals and the exposed conductive cores are partitioned by the ribs.

8. The sensor assembly as claimed in claim 7, wherein the rear ends of the metal terminals are located above the exposed conductive cores.

9. The sensor assembly as claimed in claim 3, wherein the main portion of the insulating base has two grooves opening forwards and upwards.

10. The sensor assembly as claimed in claim 3, wherein the upright portion has a guide slope to lead the insulating base into the insulating shell.

11. A sensor assembly comprising:
an insulating shell having a receiving cavity with a rear opening; and
an insulating base loaded with an electromagnetic wave sensor and metal terminals and a cable, the metal terminals being connected between the sensor and front exposed conductive cores of the cable;
wherein the insulating shell defines an upper inside and a lower inside, the lower inside has a first slope, the insulating base has an upper face and a lower face, the lower face has a second slope, a working surface of the sensor exposes to the upper face of the insulating base, the insulating base moves towards the upper inside when the second slope moves along the first slope during inserting the insulating base forwards into the receiving cavity.

12. The sensor assembly as claimed in claim 11, wherein rear ends of the metal terminals have larger pitch than front ends of the metal terminals, the front ends of the metal terminals are connected with the sensor, the rear ends of the metal terminals are connected with the front exposed conductive cores of the cable.

13. The sensor assembly as claimed in claim 12, wherein the insulating base includes a main portion holding the sensor, an upright portion sealing the insertion opening, and a transverse portion connecting with the main portion and the upright portion, and the cable extends through a round hole of the upright portion.

14. The sensor assembly as claimed in claim 13, wherein the main portion has a receiving notch recessed from the upper face and penetrating through the main portion in a direction perpendicular to the cable, and the sensor is received in the receiving notch.
